(19) United States
(12) Patent Application Publication
(10) Pub. No.: US 2025/0191804 A1
(43) Pub. Date: Jun. 12, 2025

(54) NEUTRAL BEAM AND EXTREME ULTRAVIOLET LIGHT-GENERATING DEVICE AND METHOD

(71) Applicant: SAMSUNG ELECTRONICS CO., LTD., Suwon-si (KR)

(72) Inventors: Jehoi Mun, Suwon-si (KR); Sungho Jang, Suwon-si (KR); Kyunghyun Kim, Suwon-si (KR); Sungwon Cho, Suwon-si (KR); Sangki Nam, Suwon-si (KR)

(73) Assignee: SAMSUNG ELECTRONICS CO., LTD., Suwon-si (KR)

(21) Appl. No.: 18/777,246

(22) Filed: Jul. 18, 2024

(30) Foreign Application Priority Data
Dec. 11, 2023 (KR) 10-2023-0178748

(51) Int. Cl. G21K 5/04; G21K 1/06; G21K 1/087; H05H 1/46

(52) U.S. Cl. CPC G21K 5/04; G21K 1/065; G21K 1/087; H05H 1/4645; G21K 2201/068

(57) ABSTRACT

A neutral beam and extreme ultraviolet (EUV) light-generating device capable of generating EUV light while generating a neutral beam. The neutral beam and EUV light-generating device includes: an ion beam source configured to generate an ion beam and to output the ion beam in a first direction, a first electron beam source configured to generate a first electron beam incident on the ion beam, a second electron beam source configured to generate and output a second electron beam, and a first electromagnetic control device configured to control a traveling direction of the second electron beam to cause the second electron beam to collide head-on with the ion beam to generate a neutral beam and EUV light.

### CROSS-REFERENCE TO RELATED APPLICATION

This application is based on and claims priority under 35 U.S.C. § 119 to Korean Patent Application No. 10-2023-0178748, filed on Dec. 11, 2023, in the Korean Intellectual Property Office, the disclosure of which is incorporated by reference herein in its entirety.

### BACKGROUND

The present disclosure relates to a semiconductor processing device, and more particularly, to a neutral beam and extreme ultraviolet (EUV) light-generating device and method.

As the line width of a semiconductor circuit becomes increasingly smaller, a light source with a shorter wavelength may be advantageous. For example, extreme ultraviolet (EUV) light is used as an exposure source. Due to absorption characteristics of EUV light, a reflective EUV mask is generally used in an EUV exposure process. In addition, illumination optics for transmitting EUV light to an EUV mask and projection optics for projecting EUV light reflected from the EUV mask to an exposure target may include a plurality of mirrors. In addition, in an etching process using an ion beam, a neutral atomic beam, that is, a neutral beam, may be used to address problems caused by electric charge of ions.

### SUMMARY

One or more example embodiments provide to a neutral beam and an extreme ultraviolet (EUV) light-generating device capable of generating EUV light while generating a neutral beam.

The problems to addressed by the technical idea of the present disclosure are not limited to the above-mentioned problems, and other problems not mentioned will be clearly understood by those skilled in the art from the following description.

According to an aspect of one or more example embodiments, a neutral beam and extreme ultraviolet (EUV) light-generating device includes: an ion beam source configured to generate an ion beam and to output the ion beam in a first direction; a first electron beam source configured to generate a first electron beam incident on the ion beam; a second electron beam source configured to generate and output a second electron beam; and a first electromagnetic control device configured to control a traveling direction of the second electron beam to cause the second electron beam to collide head-on with the ion beam to generate a neutral beam and EUV light.

According to a further aspect of one or more example embodiments, a neutral beam and extreme ultraviolet (EUV) light-generating device includes: an ion beam source configured to extract ions from first plasma to generate an ion beam and to output the ion beam in a first direction; a first electron beam source configured to generate a first electron beam incident on the ion beam to reduce scattering of the ion beam; a second electron beam source configured to generate and output a second electron beam, which collides with the ion beam; a first electromagnetic control device configured to control a traveling direction of the second electron beam to cause the second electron beam to collide head-on with the ion beam; and a second electromagnetic control device configured to maintain neutral atoms generated by the ion beam colliding head-on with the second electron beam and to remove ions, to generate a neutral beam of the maintained neutral atoms, the neutral beam being directed in the first direction.

According to a still further aspect of one or more example embodiments, a neutral beam and extreme ultraviolet (EUV) light-generating device includes: an ion beam source configured to extract ions from first plasma to generate an ion beam and to output the ion beam in a first direction; a first electron beam source configured to generate a first electron beam incident on the ion beam to reduce scattering of the ion beam; a second electron beam source configured to generate and output a second electron beam, which collides with the ion beam; a first electromagnetic control device configured to control a traveling direction of the second electron beam to cause the second electron beam to collide head-on with the ion beam; and an EUV collector configured to collect EUV light generated from the second electron beam colliding head-on with the ion beam and to output the EUV light in one direction and in a plane direction perpendicular to the first direction.

According to a still further aspect of one or more example embodiments, a neutral beam and extreme ultraviolet (EUV) light-generating method includes: extracting, by an ion beam source, ions from first plasma to generate an ion beam and outputting the ion beam in a first direction; generating, by a first electron beam source, a first electron beam incident on the ion beam to reduce scattering of the ion beam; generating, by a second electron beam source, a second electron beam; controlling, by a first electromagnetic control device, a traveling direction of the second electron beam to cause the second electron beam to collide head-on with the ion beam to generate EUV light and a neutral beam.

### BRIEF DESCRIPTION OF DRAWINGS

The above and other aspects and features will be more apparent from the following description of example embodiments taken in conjunction with the accompanying drawings, in which:

FIG. 1 is a conceptual diagram schematically illustrating a neutral beam and extreme ultraviolet (EUV) light-generating device according to one or more example embodiments;

FIGS. 2 and 3 are conceptual diagrams schematically illustrating neutral beam and EUV light-generating devices according to one or more example embodiments;

FIGS. 4A and 4B are conceptual diagrams of a neutral beam generating device according to a comparative example and an EUV exposure device according to a comparative example;

FIG. 5 is a graph illustrating a wavelength band of EUV light generated by the EUV light-generating device of the comparative example of FIG. 4B;

FIGS. 6A and 6B are conceptual diagrams for explaining a principle of simultaneously generating a neutral beam and EUV light by the neutral beam and EUV light-generating device of one or more example embodiments;

FIGS. 7A, 7B and 7C are conceptual diagrams for explaining a concept of EUV light generation and phase according to radiative recombination in plasma;

FIGS. 8A, 8B and 8C are conceptual diagrams for explaining a concept of phase matching of EUV light generated by a neutral beam and EUV light-generating device of one or more example embodiments;

FIG. 9A is a conceptual diagram of one collision between electrons and ions;

FIGS. 9B and 9C are graphs illustrating a back-scattering rate and intensity of EUV light according to energy of an electron beam;

FIG. 10 is a conceptual diagram of N collisions between electrons and ions;

FIGS. 11A, 11B, 12A, 12B, 13A and 13B are graphs illustrating a back-scattering rate and intensity of EUV light according to energy of an electron beam;

FIGS. 14A and 14B are graphs illustrating a degree of quantum spread at a moving position according to energy of an electron beam;

FIG. 15 is a flowchart schematically illustrating processes of a neutral beam and EUV light-generating method according to one or more example embodiments; and

FIGS. 16A, 16B, 16C and 16D are flowcharts illustrating the processes of the neutral beam and EUV light-generating method of FIG. 15 in more detail according to one or more example embodiments.

### DETAILED DESCRIPTION

Hereinafter, example embodiments will be described in detail with reference to the accompanying drawings. Like reference numerals refer to like elements, and duplicative descriptions may be omitted.

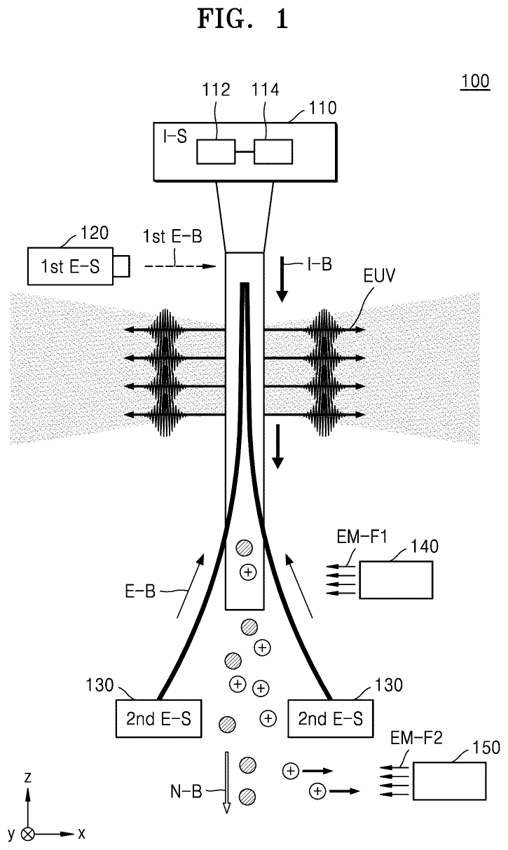

FIG. 1 is a conceptual diagram schematically illustrating a neutral beam and extreme ultraviolet (EUV) light-generating device 100 according to one or more example embodiments.

Referring to FIG. 1, the neutral beam and EUV light-generating device 100 of one or more example embodiments may include an ion beam source 110, a first electron beam source 120, a second electron beam source 130, a first electromagnetic control device 140, and a second electromagnetic control device 150.

The ion beam source 110 may generate an ion beam I-B and may output the ion beam I-B in a vertical direction, that is, a z direction, according to one or more example embodiments shown in FIG. 1. The ion beam source 110 may include a first plasma generating device 112, which generates first plasma and a first electrostatic lens 114, which extracts ions from the first plasma to generate the ion beam I-B. The first plasma generating device 112 may generate the first plasma by using capacitively coupled plasma (CCP), inductively coupled plasma (ICP), or a combination of CCP and ICP.

The first electrostatic lens 114 may extract the ions from the first plasma and may turn the ions into the ion beam I-B. The first electrostatic lens 114 may include a plurality of lenses. For example, the first electrostatic lens 114 may include, for example, a plasma lens, an extraction lens, a suppression lens, and an exit lens. The ion beam I-B having specified characteristics may be generated by controlling the shape of the first electrostatic lens 114 and a voltage applied to the first electrostatic lens 114.

In one or more example embodiments, an inert gas such as argon (Ar) or helium (He) may be used as a plasma source gas in the neutral beam and the EUV light-generating device 100. When Ar gas is used, an Ar+ ion beam may be generated by using the first electrostatic lens 114, and when He gas is used, a He²⁺ ion beam may be generated by using the first electrostatic lens 114. However, types of the plasma source gas and the resulting ion beam are not limited to the above-described materials and ion beams according to one or more example embodiments.

The first electron beam source 120 may generate a first electron beam 1st E-B and may make the first electron beam 1st E-B be incident on an upstream portion of the ion beam I-B. According to one or more example embodiments, the upstream portion of the ion beam I-B may refer to a portion of the ion beam I-B adjacent to the ion beam source 110. The first electron beam 1st E-B may be provided to prevent the ion beam I-B from being scattered by a repulsive force caused by a space charge. In addition, the first electron beam 1st E-B may reduce an influence of the space charge of the ion beam I-B on the speed and orbit of a second electron beam E-B. The first electron beam source 120 may include, for example, an electron gun. However, the first electron beam source 120 is not limited to the electron gun according to one or more example embodiments.

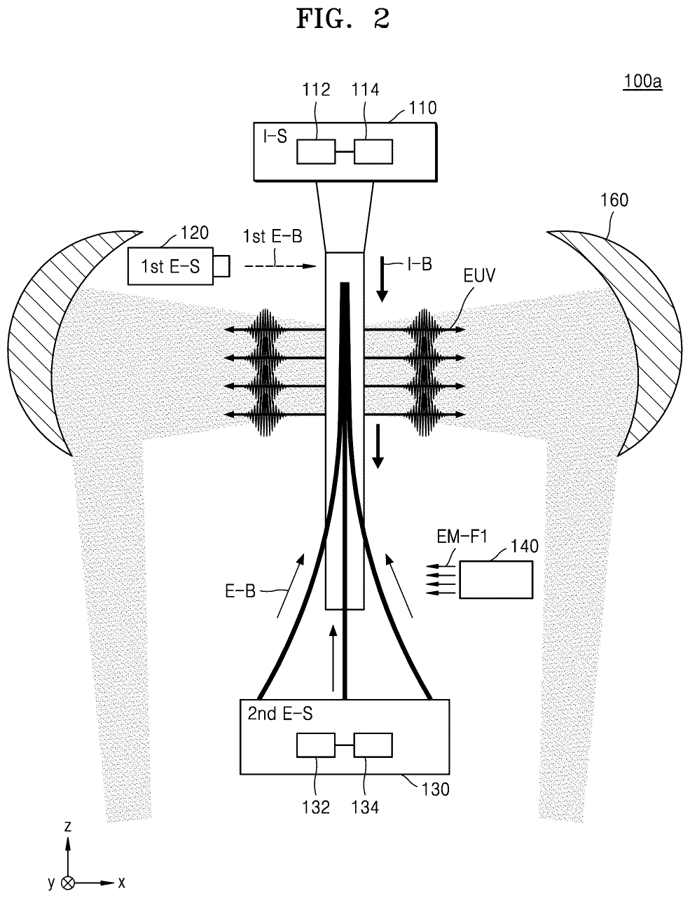

The second electron beam source 130 may generate and output the second electron beam E-B. In addition, as noted with reference to FIG. 2, the second electron beam source 130 may include a second plasma generating device 132, which may generate second plasma and a second electrostatic lens 134, which may extract electrons from the second plasma to generate the second electron beam E-B. The second plasma generating device 132 may generate the second plasma by using CCP, ICP, or a combination of CCP and ICP. The second electrostatic lens 134 may extract electrons from the second plasma and may turn the electrons into the second electron beam E-B. The second electrostatic lens 134 may include a plurality of lenses. The second electron beam E-B having specified characteristics may be generated by controlling the shape of the second electrostatic lens 134 and a voltage applied thereto. According to one or more example embodiments, unless there is confusion with the first electron beam 1st E-B, the second electron beam E-B may be referred to as an electron beam E-B.

In the neutral beam and EUV light-generating device 100 of one or more example embodiments, the second electron beam source 130 may be implemented by the second plasma generating device 132 and the second electrostatic lens 134. However, one or more example embodiments are not limited thereto, and the second electron beam source 130 may be implemented by using any type of electron accelerator device, which generates and accelerates electrons, such as an electron gun and a laser wakefield acceleration (LWFA) device. Furthermore, the second electron beam source 130 may be arranged at a position facing the ion beam source 110 in the z direction. For example, when the ion beam source 110 is arranged at the top in the z direction, the second electron beam source 130 may be arranged lower than the ion beam source 110 in the z direction. However, because the direction of the electron beam E-B from the second electron beam source 130 may be controlled by the first electromagnetic control device 140, the second electron beam source 130 does not need to be exactly opposite to the ion beam source 110 in the z direction. In FIG. 1, the second electron beam source 130 is divided into two electron beam sources, which are shown separately for convenience to show generation of a neutral beam N-B. In fact, as illustrated in FIG. 2, the electron beam E-B may be generated and output from one second electron beam source 130.

The first electromagnetic control device 140 may advance the electron beam E-B from the second electron beam source 130 in a direction opposite to a direction of the ion beam I-B while keeping the electron beam E-B parallel to the ion beam I-B. For example, when the ion beam I-B travels downward in the z direction, the electron beam E-B may travel upward in the z direction through control by the first electromagnetic control device 140. The first electromagnetic control device 140 may control the direction of the electron beam E-B by changing the orbit of the electron beam E-B by using a first electromagnetic force EM-F1.

As the electron beam E-B travels toward the ion beam I-B in parallel with the ion beam I-B through the first electromagnetic control device 140, the electron beam E-B may undergo a head-on collision with the ion beam I-B. Radiative recombination may occur between electrons of the electron beam E-B and ions of the ion beam I-B through the head-on collision between the electron beam E-B and the ion beam I-B. EUV light EUV corresponding to the sum of ionization energy of the ions and kinetic energy of the electrons may be generated by the radiative recombination. In addition, the ions combined with the electrons may become neutral atoms. For example, in FIG. 1, the radiative recombination may occur in a shaded hatched section in which EUV light components EUV are emitted.

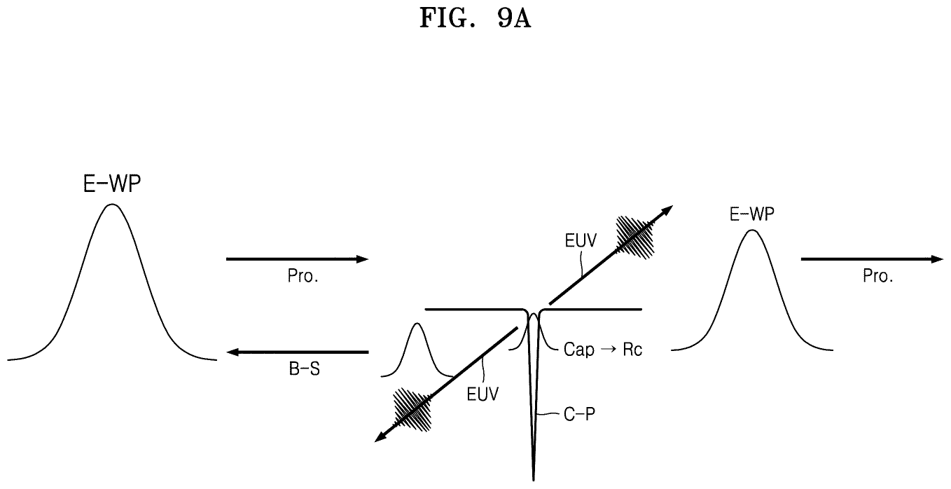

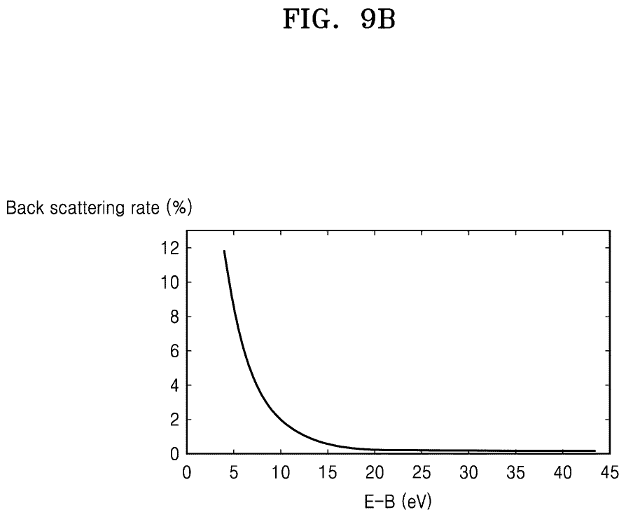

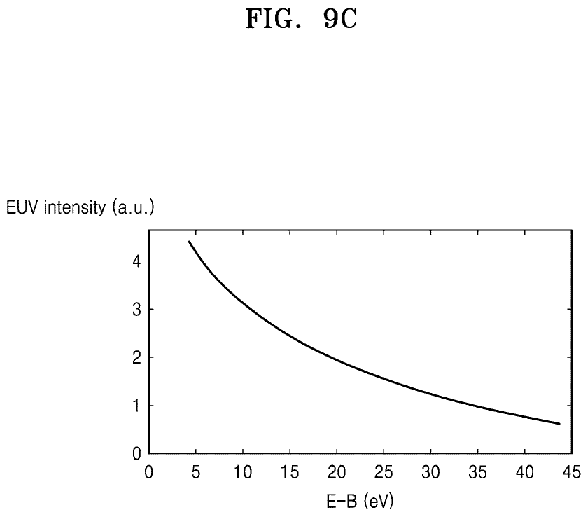

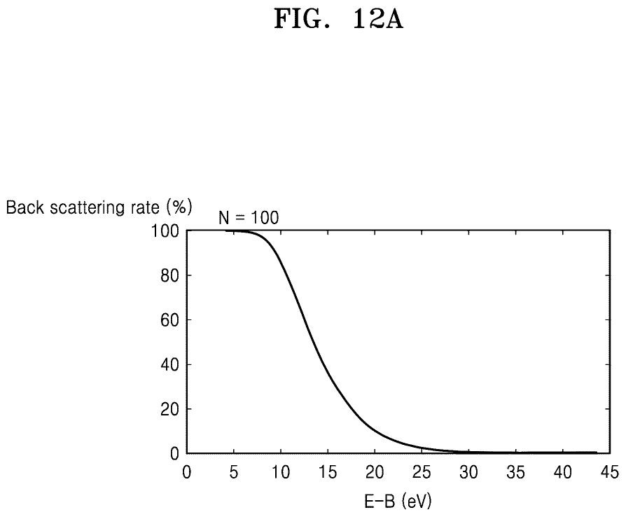

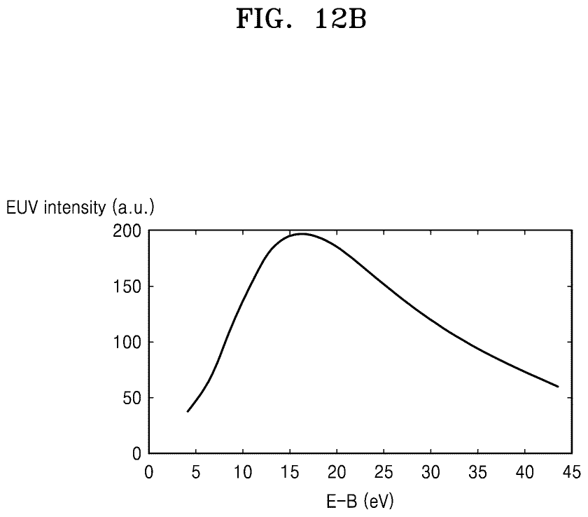

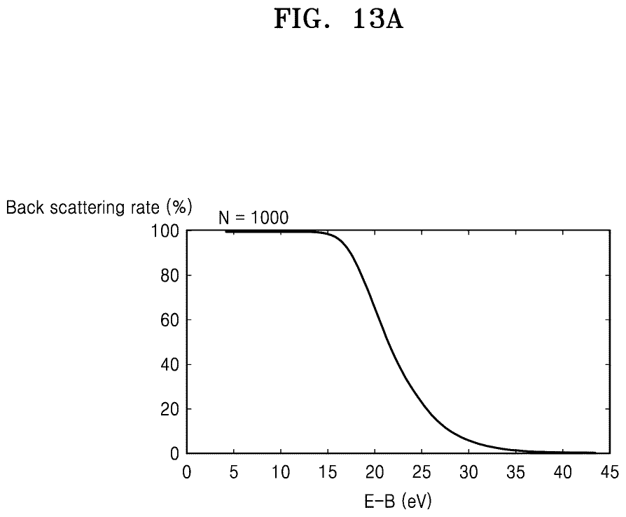

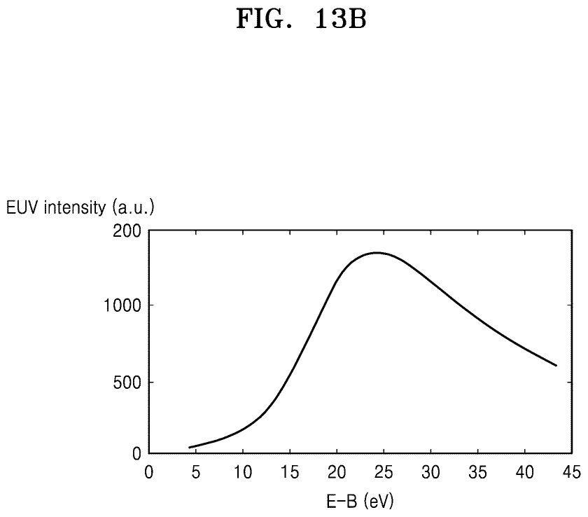

In addition, not all ions of the ion beam I-B become neutral atoms. That is, not all ions of the ion beam I-B undergo the radiative recombination with the electrons of the electron beam E-B. Therefore, as a measure to increase the probability of the radiative recombination, increasing energy of the electron beam E-B and reducing the cross-sectional area of the ion beam may be considered. One or more example embodiments to increase the probability of the radiative recombination are described below in more detail with reference to FIGS. 9A, 9B, 9C, 10, 11A, 11B, 12A, 12B, 13A, 13B, 14A and 14B.

The second electromagnetic control device 150 may generate the neutral beam formed of the neutral atoms. More specifically, after the neutral atoms are generated through the radiative recombination in an upper portion in the z direction, the ions marked + and the hatched neutral atoms may travel downward in the z direction. The second electromagnetic control device 150 may remove only ions from a beam formed of the neutral atoms and ions by using a second electromagnetic force EM-F2. In this way, by removing only ions from a downstream of the beam using the second electromagnetic control device 150, the neutral beam of the neutral atoms directed downward in the z direction may be generated. As a result, the neutral beam and EUV light-generating device 100 of one or more example embodiments may be used as a neutral beam source in a plasma etching process by using the second electromagnetic control device 150.

In order to maximize an output of the neutral beam, it may be advantageous to appropriately control the energy of the electron beam E-B. For example, it may be advantageous to increase the energy of the electron beam E-B and to maintain the energy of the electron beam E-B not to be higher than the ionization energy of the ion beam I-B. Specifically, according to one or more example embodiments with an Ar⁺ ion beam, ionization energy of a neutral Ar atom may be about 15.75 eV. When the energy of the electron beam E-B, that is, the kinetic energy of the electrons of the electron beam E-B, becomes higher than 15.75 eV, Ar atoms neutralized by electron impact ionization may be ionized again. As a result, when the energy of the electron beam E-B is excessively high, generation efficiency of Ar neutral atoms may decrease so that the output of the neutral beam may decrease. Therefore, in order to maximize the output of the neutral beam, it is advantageous to optimally control the energy of the electron beam E-B according to variables such as density and spatial distribution of the ion beam I-B and the electron beam E-B. For example, according to one or more example embodiments, the energy of the electron beam E-B may be controlled by controlling a voltage applied to the second electrostatic lens 134.

The neutral beam and EUV light-generating device 100 of one or more example embodiments may generate the neutral beam and the EUV light at the same time by effectively utilizing a radiative recombination process, which is a recombination process of ions and electrons. Specifically, by colliding the ion beam I-B and the electron beam E-B head-on to generate the radiative recombination, the ions are converted into the neutral atoms to generate the neutral beam of the neutral atoms, and the EUV light corresponding to the sum of the ionization energy of the ions and the kinetic energy of the electrons may be generated as the electrons are captured by the ions. In addition, the neutral beam and EUV light-generating device 100 of one or more example embodiments may fundamentally address problems such as contamination by particles and deterioration of performance of a metal-reflector over time in the neutral beam generating method using the metal-reflector by using the radiative recombination between the ions and the electrons. In addition, the neutral beam and EUV light-generating device 100 of one or more example embodiments may generate a high output neutral beam and/or high intensity EUV light with a specified wavelength by controlling the energy of the electron beam E-B.

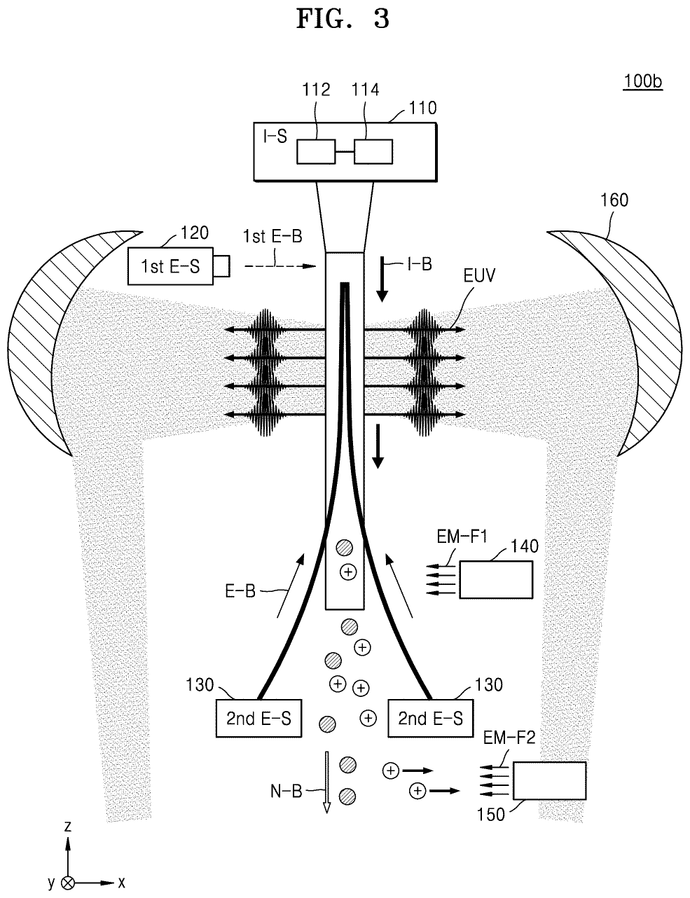

FIGS. 2 and 3 are conceptual diagrams schematically and respectively illustrating neutral beam and EUV light-generating devices 100a and 100b according to one or more example embodiments. Duplicative description previously given with reference to FIG. 1 may be omitted.

Referring to FIG. 2, the neutral beam and EUV light-generating device 100a of one or more example embodiments may be different from the neutral beam and EUV light-generating device 100 of FIG. 1 in that the second electromagnetic control device 150 may be omitted and an EUV collector 160 is further included. Specifically, the neutral beam and EUV light-generating device 100a of one or more example embodiments may include an ion beam source 110, a first electron beam source 120, a second electron beam source 130, a first electromagnetic control device 140, and the EUV collector 160. According to one or more example embodiments, the ion beam source 110, the first electron beam source 120, the second electron beam source 130, and the first electromagnetic control device 140 are similar to the description of the neutral beam and EUV light-generating device 100 of FIG. 1.

The EUV collector 160 may collect the EUV light generated by the head-on collision between the ion beam I-B and the electron beam E-B and the resulting radiative recombination and may output the EUV light in one direction. As noted with reference to FIG. 2, when the ion beam I-B and the electron beam E-B collide head-on in the z direction, the EUV light may travel in a radial form on an x-y plane perpendicular to the z direction. For example, the EUV collector 160 may collect the EUV light traveling on the x-y plane and may output the EUV light to be directed downward in the z direction. However, the direction in which the EUV light travels from the EUV collector 160 is not limited to downward in the z direction. For example, the angle of the EUV collector 160 may be appropriately controlled so that the EUV light is directed in a specified direction. As a result, the neutral beam and EUV light-generating device 100a of one or more example embodiments may be used as an EUV source in an EUV exposure process by using the EUV collector 160.

In order to generate EUV light with the specified wavelength, it is advantageous to appropriately control the energy of the electron beam E-B. For example, it may be advantageous to increase the energy of the electron beam E-B so that the sum of the ionization energy of the ion beam I-B and the energy of the electron beam E-B corresponds to energy of the EUV light with the specified wavelength. Specifically, according to one or more example embodiments with an He²⁺ ion beam, ionization energy of He¹⁺ may be about 52.5 eV. When EUV light of 13.5 nm is to be generated, energy of the EUV light of 13.5 nm may be about 91.85 eV. Therefore, when the energy of the electron beam E-B, that is, the kinetic energy of the electrons of the electron beam E-B is 39.35 eV, EUV light with a wavelength corresponding to 52.5 eV+39.35 eV=91.85 eV, that is, the EUV light of 13.5 nm, may be generated by the radiative recombination through the head-on collision between the ion beam I-B and the electron beam E-B. According to one or more example embodiments, the energy of the electron beam E-B may be controlled by controlling a voltage applied to the second electrostatic lens 134. In addition, the EUV light may be emitted in a direction perpendicular to the z direction, which is the head-on collision direction between the ion beam I-B and the electron beam E-B, that is, onto the x-y plane.

When the energy of the electron beam E-B is increased, the probability of radiative recombination of He²⁺ ions and electrons may be increased from a macro perspective so that a larger amount of EUV light may be obtained. However, because EUV light with a wavelength corresponding to the sum of the ionization energy of He¹⁺ and the energy of the electron beam E-B is generated, the wavelength of the generated EUV light may become shorter as the energy of the electron beam E-B increases. Accordingly, EUV light with various specified wavelengths may be generated by controlling a type of the ions of the ion beam I-B and the energy of the electron beam E-B.

Referring to FIG. 3, the neutral beam and EUV light-generating device 100b of one or more example embodiments may be different from the neutral beam and EUV light-generating devices 100 and 100a according to one or more example embodiments shown in FIGS. 1 and 2 in that both a second electromagnetic control device 150 and an EUV collector 160 may be included. Specifically, the neutral beam and EUV light-generating device 100b of one or more example embodiments may include an ion beam source 110, a first electron beam source 120, a second electron beam source 130, a first electromagnetic control device 140, the second electromagnetic control device 150, and the EUV collector 160. The ion beam source 110, the first electron beam source 120, the second electron beam source 130, the first electromagnetic control device 140, and the second electromagnetic control device 150 are similar to the description of the neutral beam and EUV light-generating device 100 of FIG. 1, and the EUV collector 160 is similar to the description of the neutral beam and EUV light-generating device 100a of FIG. 2.

The neutral beam and EUV light-generating device 100b of one or more example embodiments may be used as a neutral beam source in a plasma etching process by using the second electromagnetic control device 150. In addition, the neutral beam and EUV light-generating device 100b of one or more example embodiments may be used as an EUV source in an EUV exposure process by using the EUV collector 160.

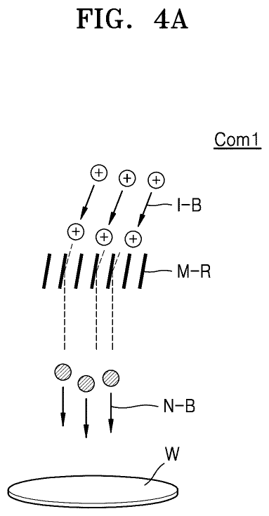

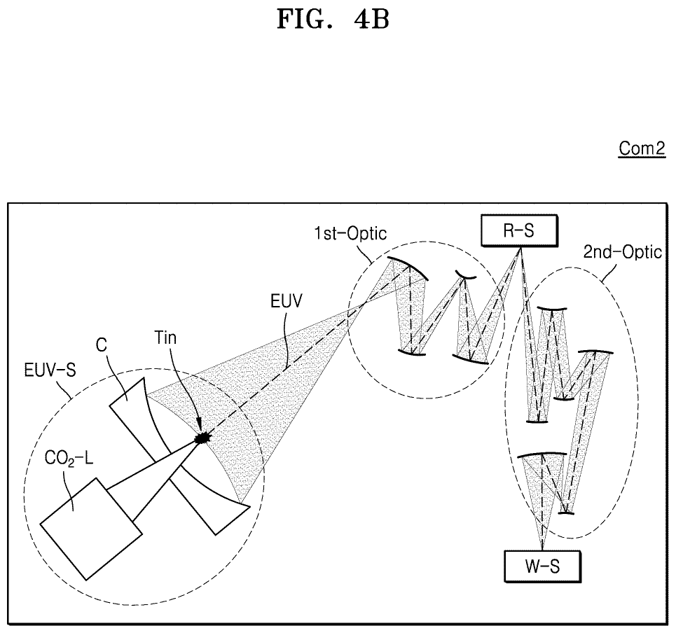

FIGS. 4A and 4B are conceptual diagrams of a neutral beam generating device Com1 according to a comparative example and an EUV exposure device Com2 according to a comparative example.

Referring to FIG. 4A, when a wafer is etched by using an ion beam in a plasma etching process, charges of ions may accumulate on a surface of a wafer, thereby reducing process precision. Accordingly, the problem of charge accumulation may be addressed by using a neutral beam formed of neutral atoms instead of an ion beam. In a comparative method of generating the neutral beam, as illustrated in the neutral beam generating device Com1 of the comparative example of FIG. 4A, the ion beam I-B is incident on a metal-reflector M-R, and the ion beam I-B is converted into the neutral beam N-B through charge exchange between a metal surface and the ions. However, in the method in which the metal-reflector is used, the performance of the metal-reflector deteriorates over time due to etching on the metal surface, and the surface of the wafer W is contaminated by particles generated by a metal structure. On the other hand, because the neutral beam and EUV light-generating devices 100, 100a, and 100b of one or more example embodiments do not use metal-reflectors, problems caused by the metal-reflectors can be addressed.

Referring to FIG. 4B, in a comparative method of generating the EUV light, a high-energy CO₂ laser is concentrated and injected into a tin droplet, and tin plasma densely packed in a small space on a micrometer scale is generated to collect EUV light generated by the plasma and to output the EUV light. FIG. 4B illustrates the EUV exposure device Com2 of a comparative example including an EUV source of the above-described method.

To briefly describe the EUV exposure device Com2 of the comparative example, the EUV exposure device Com2 of the comparative example may include an EUV source EUV-S, a first optical system 1st-Optic, a reticle stage R-S, a second optical system 2nd-Optic, and a wafer stage W-S. The EUV source EUV-S may generate plasma by injecting the high-energy CO₂ laser CO₂-L into the tin droplet, and the EUV light EUV generated by the plasma may be condensed and output by a collector C. The first optical system 1st-Optic includes a plurality of mirrors and may transmit EUV light EUV from the EUV source EUV-S to a reticle on the reticle stage R-S through reflection by the plurality of mirrors. Here, the reticle may refer to an EUV mask.

The reticle may be arranged on the reticle stage R-S and the reticle stage R-S may move in x and y directions on the x-y plane and in the z direction perpendicular to the x-y plane. In addition, the reticle stage R-S may rotate about a z axis, an x axis, or a y axis. By the movement and rotation of the reticle stage R-S, the reticle may move in the x, y, or z direction and may also rotate about the x, y, or z axis. The reticle may have a structure including a reflective multilayer for reflecting EUV light onto a substrate formed of a low thermal expansion material (LTEM) such as quartz, and an absorption layer pattern formed on the reflective multilayer.

The second optical system 2nd-Optic may include a plurality of mirrors and may transmit the EUV light reflected from the reticle to a wafer on the wafer stage W-S through reflection of the plurality of mirrors. The wafer to be EUV exposed is arranged on the wafer stage W-S and the wafer stage W-S may move in the x and y directions on the x-y plane and in the z direction perpendicular to the x-y plane. In addition, the wafer stage W-S may rotate about the z axis, the x axis, or the y axis. By the movement and rotation of the wafer stage W-S, the wafer may move in the x, y, or z direction and may also rotate about the x, y, or z axis.

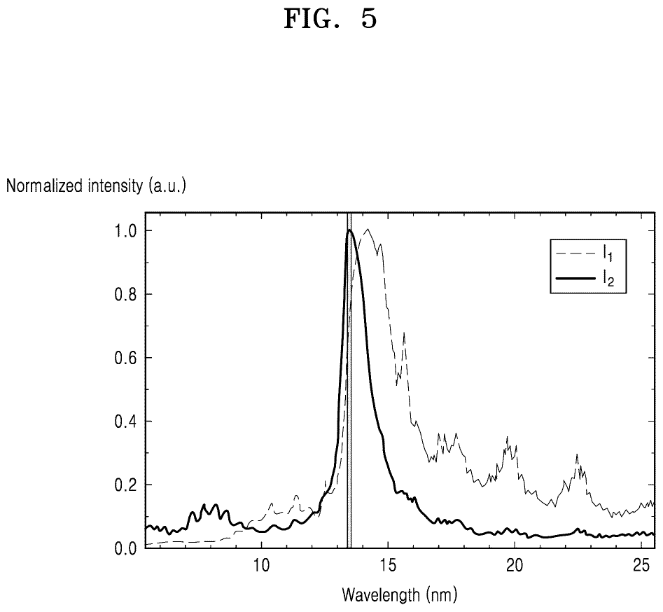

In the case of the method of generating the EUV light by the EUV exposure device Com2 of the comparative example or the EUV source EUV-S included therein, it may be very difficult to generate and control the tin droplet, to increase the energy of the CO₂ laser, to precisely control a beam, and to control debris. In addition, as described with reference to FIG. 5 below, there is a problem that the EUV light of the EUV source EUV-S includes out-of-band emission as well as in-band emission. However, the neutral beam and EUV light-generating devices 100, 100a, and 100b of one or more example embodiments with relatively low control abilities may generate the high intensity EUV light with the specified wavelength by controlling the energy of the electron beam E-B.

FIG. 5 is a graph illustrating a wavelength band of EUV light generated by the EUV light-generating device of the comparative example of FIG. 4B and a wavelength band of EUV light generated by using lasers of two intensities I₁ and I₂. The x axis represents the wavelength and the unit is nm, and the y axis represents the intensity and the unit is an arbitrary unit.

Referring to FIG. 5, when EUV light emitted from tin plasma formed of a high-energy laser is used, not only a specified wavelength region, for example, 13.5 nm, but also the out-of-band emission may be obtained. The out-of-band emission may be absorbed by the optical system of the EUV exposure device that reflects only the in-band emission, generating heat or causing damage, and some may be transferred to the wafer to act as noise in the EUV exposure process. For example, in the graph of FIG. 5, a thin pillar may correspond to the specified wavelength region and a spectrum and an intensity of the EUV light change depending on the intensity of the lasers.

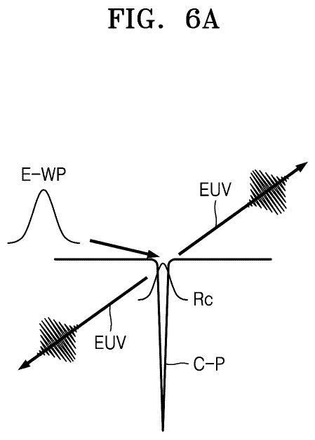

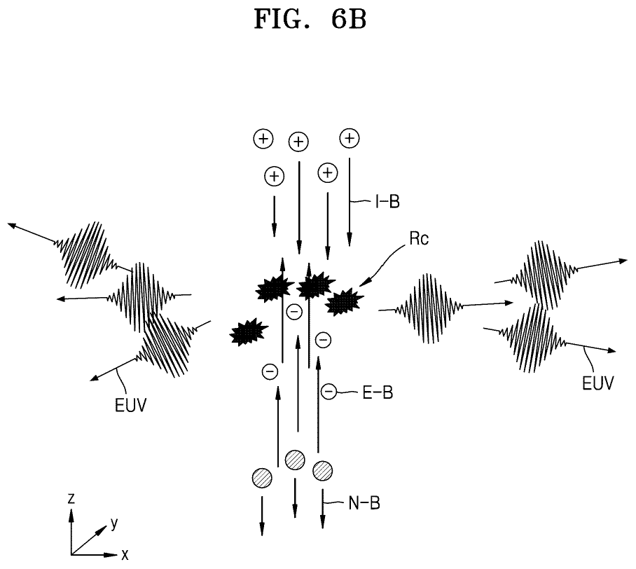

FIGS. 6A and 6B are conceptual diagrams for explaining a principle of simultaneously generating a neutral beam and EUV light by the neutral beam and EUV light-generating device of one or more example embodiments. Description is given with reference to FIG. 1 together and duplicative description previously given with reference to FIGS. 1, 2, 3, 4A, 4B and 5 may be omitted.

Referring to FIGS. 6A and 6B, in the neutral beam and EUV light-generating device 100 of one or more example embodiments, the ion beam I-B of the ion beam source 110 and the electron beam E-B of the second electron beam source 130 may collide head-on to generate and emit the EUV light by the radiative recombination of the electrons and the ions. From an atomic unit point of view, spatially overlapping, that is, colliding ions and electrons, may be recombined into atoms, and energy corresponding to the sum of the ionization energy of the atoms and the kinetic energy of the electrons may be emitted as EUV photons, that is, the EUV light EUV. Therefore, a proportional amount of EUV light EUV may be generated at the same time as neutral atoms are generated. For reference, the radiative recombination Rc may be attributed to light being emitted while the ions and the electrons recombine into the atoms.

In FIG. 6A, the electrons are expressed as an electron wave packet E-WP and the ions are expressed as Coulomb potential C-P. Therefore, radiative recombination Rc occurs as the electrons E-WP of the electron beam E-B traveling in one direction are captured by the ions C-P of the ion beam I-B, and the EUV light EUV generated by the radiative recombination Rc may be emitted in a direction perpendicular to the two beams.

In FIG. 6B, the electrons and the ions are expressed as spherical particles. Therefore, the ions of the ion beam I-B traveling downward in the z direction collide head-on with the electrons of the electron beam E-B traveling upward in the z direction and the radiative recombination Rc occurs. The EUV light EUV generated by the radiative recombination Rc may be emitted in the direction perpendicular to the z direction, that is, onto the x-y plane. In addition, the neutral atoms converted from the ions by the radiative recombination Rc may form the neutral beam N-B while continuously traveling in the z direction according to the law of conservation of momentum.

In terms of generating the neutral beam N-B, the neutral beam and EUV light-generating device 100 of one or more example embodiments uses the radiative recombination Rc of the electrons and the ions to generate the neutral beam N-B with high straightness through conservation of momentum, while eliminating the problem of contamination due to particle generation. In terms of generating the EUV light EUV, the neutral beam and EUV light-generating device 100 of one or more example embodiments uses the radiative recombination Rc of the electrons and the ions to generate the EUV light EUV through conservation of energy, while controlling the EUV light EUV to have the specified wavelength. According to one or more example embodiments, polarization control may also be performed.

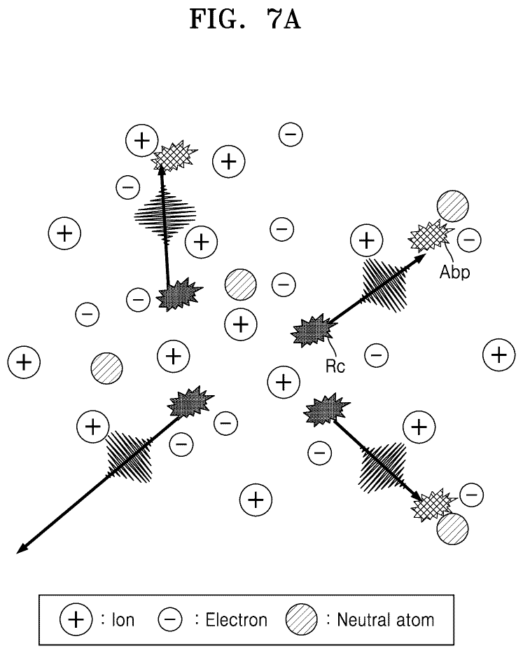

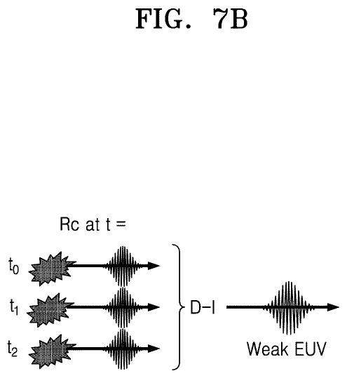

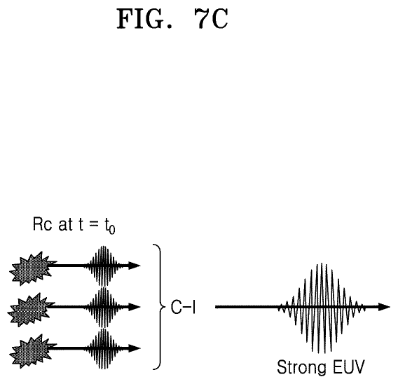

FIGS. 7A, 7B and 7C are conceptual diagrams for explaining a concept of EUV light generation and phase according to radiative recombination in plasma.

Referring to FIGS. 7A, 7B and 7C, in the case of bulk plasma, that is, from a macro perspective, the emission of the EUV light may not be noticeable due to the following two factors.

First, as illustrated in FIG. 7A, the EUV light generated by the radiative recombination Rc in a deep part of the plasma, not an outer boundary, may be reabsorbed Abp by surrounding atoms or ions to generate other electrons and ions. Second, as illustrated in FIG. 7B, the collision between the ions and the electrons in the plasma occur at random times t₀, t₁, and t₂, and the EUV photons generated at the random times t₀, t₁, and t₂ have random phases. Therefore, although the EUV photons sometimes cause constructive interference with one another, most of the EUV photons cause destructive interference D-I so that EUV light with low intensity is emitted. Compared to FIG. 7B, FIG. 7C illustrates that, when the EUV photons are generated at the same time t₀, the EUV photons have the same phase and cause constructive interference C-I with one another so that EUV light with high intensity is emitted.

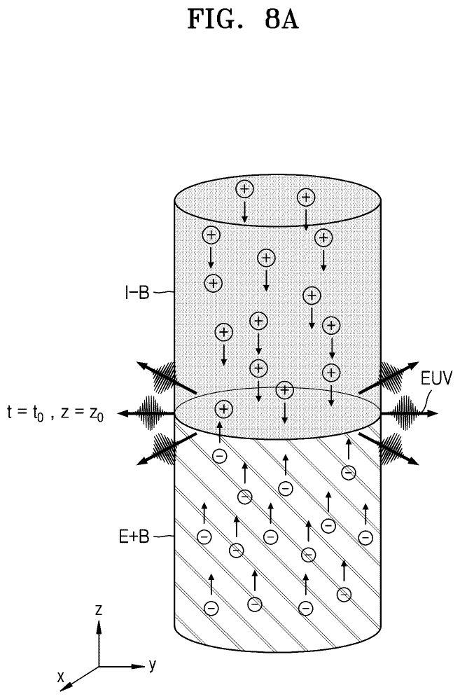

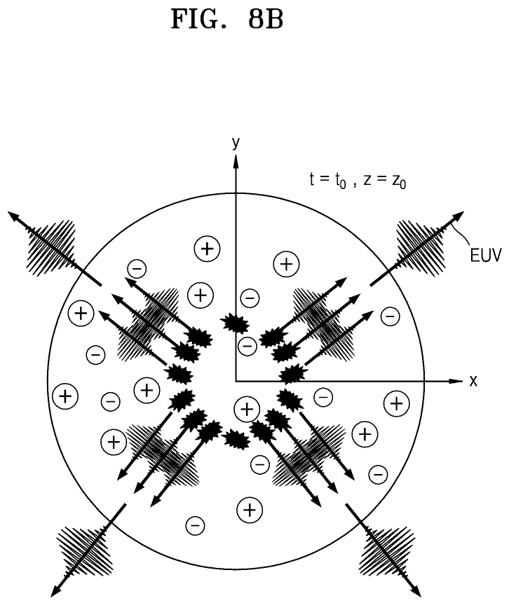

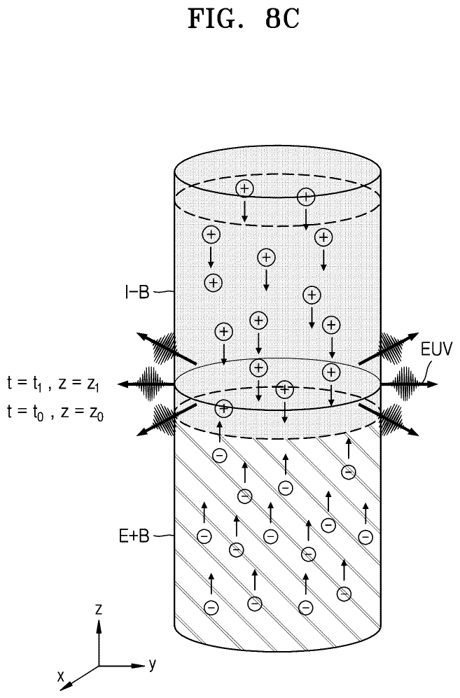

FIGS. 8A, 8B and 8C are conceptual diagrams for explaining a concept of phase matching of EUV light generated by a neutral beam and EUV light-generating device of one or more example embodiments. Description is given with reference to FIG. 1 together and duplicative description previously given with reference to FIGS. 1, 2, 3, 4A, 4B, 5, 6A, 6B, 7A, 7B and 7C may be omitted.

Referring to FIGS. 8A, 8B and 8C, in the neutral beam and EUV light-generating device 100 of one or more example embodiments, when the ion beam I-B and the electron beam E-B collide head-on in the z direction, a dipole generated by interaction between the ion beam I-B and the electron beam E-B is formed in the z direction, and light, for example, the EUV light EUV may be emitted in a direction perpendicular to the dipole. In other words, as illustrated in FIG. 8A, the EUV light EUV may be emitted in the direction perpendicular to the z direction, that is, onto the x-y plane. Therefore, compared to EUV light generated by plasma formed of randomly moving ions, atoms, and electrons, the EUV light EUV generated by the neutral beam and EUV light-generating device 100 of one or more example embodiments may be less absorbed by surrounding atoms and ions.

FIG. 8A illustrates the ion beam I-B and the electron beam E-B in three dimensions. Specifically, FIG. 8A illustrates that a wavefront of the ion beam I-B and a wavefront of the electron beam E-B meet each other at a time t₀ and a position z₀ in the z direction. That is, the ion beam I-B and the electron beam E-B may collide with each other at the time t₀ and the position z₀.

FIG. 8B illustrates the ion beam I-B and the electron beam E-B of FIG. 8A in a plan view at the time t₀ and the position z₀. As noted with reference to FIG. 8B, because the EUV photons are generated at the same time t₀ and the position z₀, the EUV photons forming a concentric circle with respect to the center on the x-y plane may cause constructive interference with each other to emit the high intensity EUV light EUV. In this way, when the macro scale ion beam I-B and electron beam E-B artificially collide head-on, the EUV light EUV generated at a junction surface, at which the two beams collide with each other at the position z₀ in the z direction, may be simultaneously emitted at all points of the junction surface. In addition, the EUV light EUV may be phase-matched, causing constructive interference and allowing EUV light EUV with higher intensity to be emitted at the macro scale. In general, when multiple light components cause constructive interference with one another, light with intensity significantly increased by 10 to 1,000 times or more may be obtained compared to the light components generated at random times in the same volume and randomly causing constructive and destructive interference. In addition, because the total amount of EUV photons generated by the recombination of the ions and the electrons is proportional to the total amount of neutral atoms generated, the emission of a large amount of EUV light may signify the generation of a large amount of neutral atoms.

FIG. 8C illustrates the ion beam I-B and the electron beam E-B in three dimensions at a time t₁ and a position z₁. The wavefront of the electron beam E-B moves upward in the z direction at the time t₁ and the position z₁, and accordingly, at the time t₁ and the position z₁, the EUV light may be emitted in the direction perpendicular to the z direction, that is, onto the x-y plane. When ignoring changes in beam speed and orbit due to space charge, that is, assuming that speeds of the ion beam I-B and the electron beam E-B are constant, the EUV photons at the time t₁ and the position z₁ may cause constructive interference with one another to emit the high intensity EUV light EUV. In FIG. 8C, the dashed line may correspond to the time t₀ and the position z₀. The above-described features may also be explained by the concept that the wavefront of the ion beam I-B moves downward in the z direction at the time t₁ and the position z₁.

As the width of the ion beam I-B in the direction perpendicular to the z direction is reduced, the amount of EUV light that is reabsorbed after being emitted may be reduced. According to one or more example embodiments, the width of the ion beam I-B may correspond to the diameter of the horizontal cross-section of a cylinder of the ion beam I-B in FIG. 8A. In addition, when a mean free path, which is a distance by which the electrons penetrate the ion beam and travel straight, is sufficiently long, the amount of the EUV light EUV may be increased in proportion to a range in the z direction in which the electron beam E-B overlaps with the ion beam I-B. Furthermore, because the total amount of EUV photons generated by the recombination of the ions and the electrons is proportional to the total amount of neutral atoms generated, as the amount of the EUV light EUV increases, the generation efficiency of the neutral atoms may also increase so that a high intensity neutral beam may be generated. Because the EUV light EUV is polarized and generated only in the z direction, the polarization of the EUV light EUV may be automatically controlled.

When the ion beam I-B and the electron beam E-B are incident parallel to each other and collide head-on, the higher the energy of the electron beam E-B, the more amount of EUV light EUV that may be generated. There may be the following two possible reasons as to why using the high energy electron beam E-B generates a larger amount of EUV light EUV.

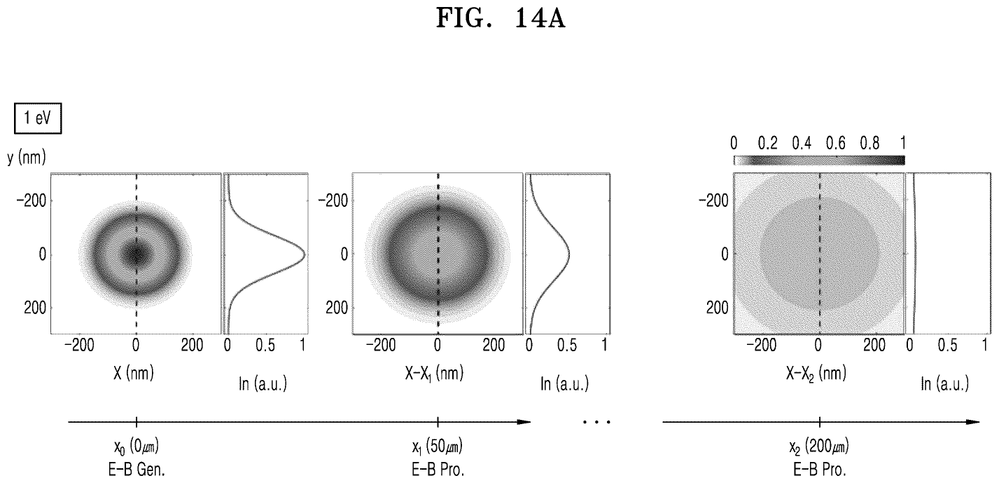

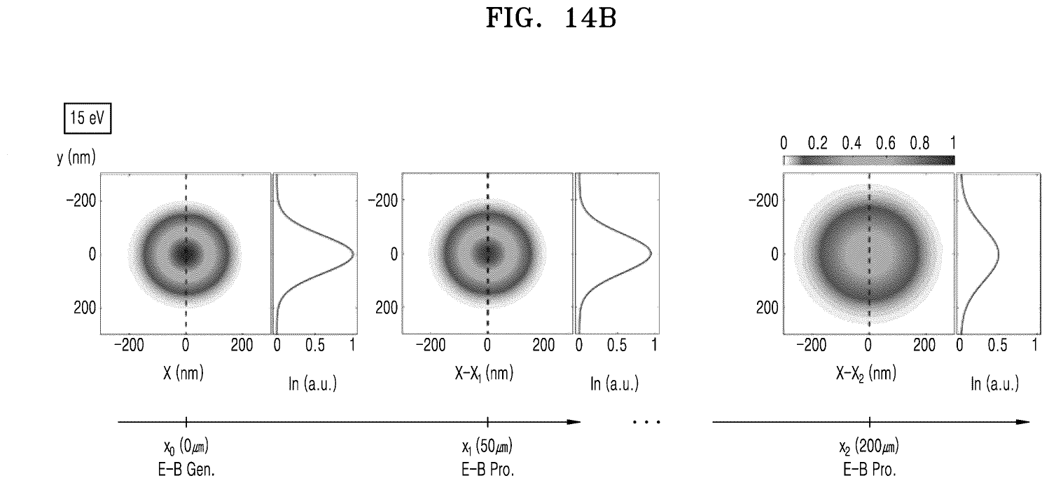

First, when the kinetic energy of the electrons of the electron beam E-B is high, the mean free path in the ion beam I-B increases. As a result, the probability that the electrons recombine with the ions may increase. Second, when the kinetic energy of electrons in the electron beam E-B is high, less quantum spread occurs so that the probability that the electrons recombine with the ions may increase. The first possible reason is described in detail below with reference to FIGS. 9A, 9B, 9C, 10, 11A, 11B, 12A, 12B, 13A and 13B, and the second possible reason is described in detail below with reference to FIGS. 14A and 14B.

FIGS. 9A, 9B and 9C are a conceptual diagram of one collision between electrons and ions, and graphs illustrating a back-scattering rate and intensity of EUV light according to energy of an electron beam. In the graph of FIG. 9B, the x axis represents the kinetic energy of the electron beam E-B and a unit is eV and the y axis represents the back-scattering rate. In the graph of FIG. 9C, the x axis represents the kinetic energy of the electron beam E-B and a corresponding unit is eV and the y axis represents the intensity of the EUV light and a corresponding unit is an arbitrary unit.

Referring to FIGS. 9A, 9B and 9C, in FIG. 9A, a quantum mechanical collision phenomenon in a one-dimensional space between a single electron and a single ion is one-dimensionally modeled by using a frame that moves together with the ion, that is, a frame in which the ion is stationary. In the one-dimensional model, a part of the electron wave packet E-WP traveling in one direction Pro. is back-scatteredB-S by the Coulomb potential C-P of the ion, and the other part of the electron wave packet E-WP traveling in the one direction Pro. is captured Cap. by the ion to emit the EUV light EUV through the radiative recombination Rc. In addition, most of the electron wave packet E-WP passes through the ions and proceeds forward in the direction Pro.

By numerically calculating the time-dependent Schrödinger equation of the one-dimensional model, the back-scattering probability according to the energy of the incident electron beam I-E, that is, the kinetic energy of the electrons, may be calculated. In addition, the intensity of the EUV light, which is a value proportional to the probability of the radiative recombination, may be calculated by using a wave function of the electron ψ(x,t) and a ground state wave function of the atom χ(x,t) obtained through the time-dependent Schrödinger equation.

For reference, when calculating the back-scattering probability and the intensity of the EUV light, the ionization energy of the ground state of the ion potential is modeled to be substantially equal to the ionization energy (15.75 eV) of the Ar atom, and the back-scattering probability and the intensity of the EUV light are calculated by using a semi-classical model in which the EUV light is treated as a classical wave and the electrons are treated as quantum mechanics. As a result, the probability of generating the neutral atoms may be calculated in arbitrary units rather than an absolute number. In order to calculate the absolute radiative recombination probability, it is necessary to apply a quantum electrodynamic model that deals with not only the electrons but also the EUV light quantum mechanically. However, because it is sufficient for the neutral beam and EUV light-generating device 100 of one or more example embodiments to explain the principle of the radiative recombination by using the semi-classical model, the quantum-electrodynamic model is not mentioned.

As noted with reference to FIGS. 9B and 9C, there is a significant change in the back-scattering probability and the radiative recombination probability depending on the energy of the electrons colliding with the ions, and both the back-scattering probability and the radiative recombination probability tend to increase as the energy of the electrons decreases. According to one or more example embodiments, the probability of the radiative recombination may be proportional to the intensity of the EUV light. Looking at this result alone, it may be determined that the lower the kinetic energy of the incident electrons, the more the radiative recombination occurs. However, this is the result when the electron interacts with only one ion, and may be completely different from the result when the electron interacts with multiple ions. Hereinafter, a result when the electron interacts with the multiple ions is described.

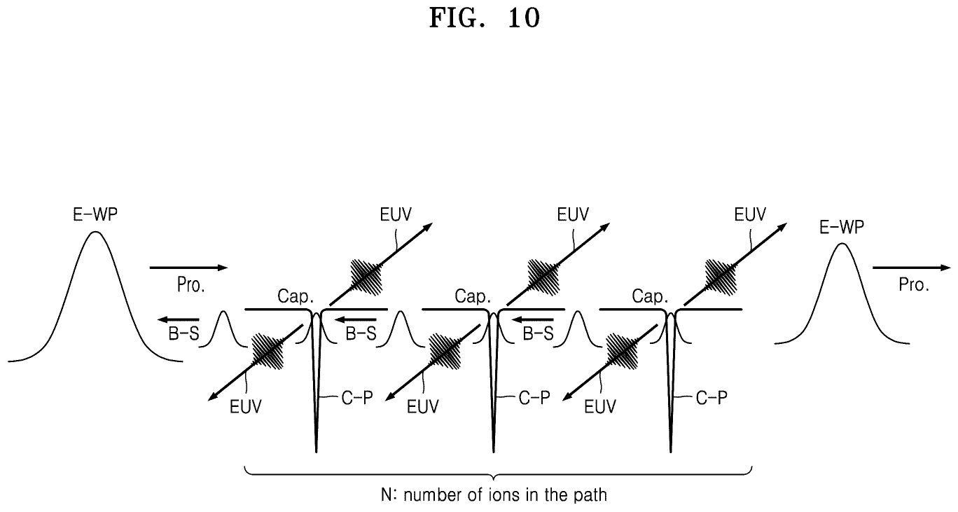

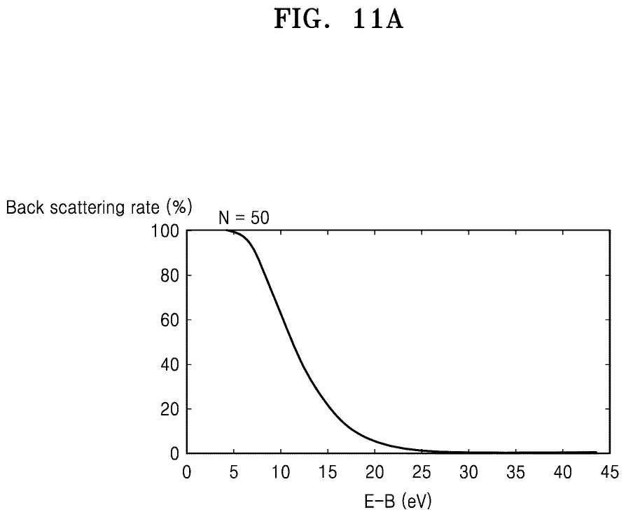

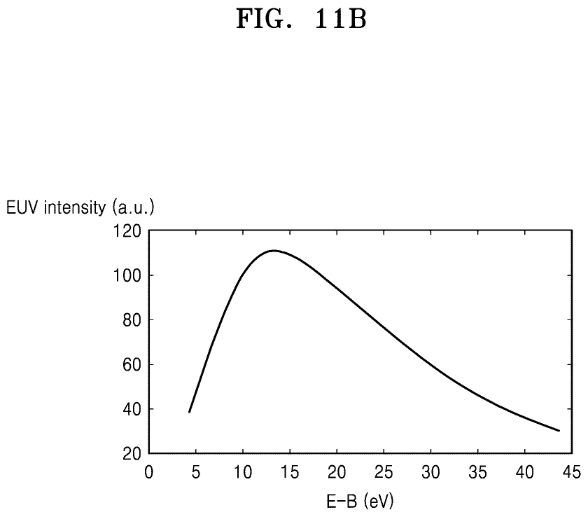

FIGS. 10, 11A, 11B, 12A, 12B, 13A and 13B are a conceptual diagram of N collisions between electron and ions, and graphs illustrating a back-scattering rate and intensity of EUV light according to energy of an electron beam. In the graphs of FIGS. 11A, 12A, and 13A, the x axis represents the kinetic energy of the electron beam E-B and a unit is eV and the y axis represents the back-scattering rate. In the graphs of FIGS. 11B, 12B, and 13B, the x axis represents the kinetic energy of the electron beam E-B and a unit is eV and the y axis represents the intensity of the EUV light and a unit is an arbitrary unit.

Referring to FIGS. 10, 11A, 11B, 12A, 12B, 13A and 13B, when the process of the electron passing through one ion colliding with another ion is repeated N times (N is an integer greater than 2) as illustrated in FIG. 10, the total back-scattering probability W_{N}(p₀) and the intensity I_{N}(p₀) of the EUV light generated through the total radiative recombination may be calculated by the following Equations (1) and (2).

$${W}_{N} ( {p}_{0} ) = 1 - {[ 1 - w ( {p}_{0} ) ]}^{N} \qquad EQUATION ( 1 )$$

$${I}_{N} ( {p}_{0} ) = {{\sum }^{N - 1}}_{n = 0} {I}_{0} ( {p}_{0} ) * {[ 1 - w ( {p}_{0} ) ]}^{N} \qquad EQUATION ( 2 )$$

wherein p₀ represents initial momentum of the electron (the kinetic energy=(p₀²)/(2mₑ) and mₑ is electron mass), w(p₀) represents the back-scattering probability that occurs in one collision with a single ion, and I₀(p₀) represents the intensity of the EUV light generated by the radiative recombination that occurs in one collision with a single ion.

FIGS. 11A, 11B, 12A, 12B, 13A and 13B illustrate the total back-scattering probabilities and the probabilities of radiative recombination when N is 50, 100, and 1000, respectively. For reference, because the probability of the radiative recombination is proportional to the intensity of the EUV light, the probability of the radiative recombination may be treated as having substantially the same meaning as the intensity of the EUV light. It may be noted with reference to FIGS. 11A, 12A, and 13A that, as a value of N increases, a range of energy of electron in which 100% back-scattering occurs increases. In addition, it may be noted with reference to FIGS. 11B, 12B, and 13B that, as the value of N increases, more EUV light may be obtained when high-energy electron are incident. Specifically, for example, when N is 1000, comparing a case in which the kinetic energy of the electron is 4 eV with a case in which the kinetic energy of the electron is 15 eV, it may be noted that EUV light with intensity that is about 50 times higher is generated in the case in which the kinetic energy of the electron is 15 eV. This is because, when the kinetic energy of the electron is high, the electron may penetrate deeper into the ion beam and may collide with more ions to generate more EUV light.

FIGS. 14A and 14B are graphs illustrating a degree of quantum spread at a moving position according to the energy of the electron beam, and a case in which the kinetic energy of the electron is 1 eV and a case in which the kinetic energy of the electron is 15 eV, respectively. In the graphs of FIGS. 14A and 14B, the bottom straight arrow represents a position of an electron wave packet in the x direction. In addition, in each of the graphs of FIGS. 14A and 14B, the x axis and the y axis of each of the three graphs on the left represent a distance from the center of the electron wave packet and a corresponding unit is nm, and each of the three graphs on the right represents intensity of the electron wave packet and a corresponding unit is an arbitrary unit.

Referring to FIGS. 14A and 14B, it may be stated that the amount of electrons back-scattered in the one-dimensional model of FIGS. 9A, 9B, 9C, 10, 11A, 11B, 12A, 12B, 13A and 13B is proportional to the amount of electrons that are scattered at all angles in a three-dimensional model and no longer travel straight. Therefore, in general, the same conclusion may be obtained by applying the results of the one-dimensional model to the three-dimensional model. However, in the three-dimensional model, the quantum spread in a direction perpendicular to a direction of the beam occurs, which does not occur in the one-dimensional model. The degree of the quantum spread varies depending on an initial state of the beam. However, considering a relatively fast electron (15 eV) and a relatively slow electron (1 eV) moving the same distance, as illustrated in FIGS. 14A and 14B, the degree of the quantum spread is larger in the slow electron (1 eV). Therefore, when a higher energy electron beam is used, because the effect of the quantum spread is reduced, the electrons collide head-on and interact with a larger amount of ions while maintaining high straightness so that more EUV light may be generated.

For reference, in FIGS. 14A and 14B, an initial electron wave packet may have a spatial 1/e radius of about 100 nm. In 1/e, e may refer to a natural constant. In addition, FIGS. 14A and 14B illustrate a spatial distribution that varies as the electron wave packet moves straight in the x direction at x₀=0, x₁=50, and x₂=200. In addition, the dynamics of the electron wave packet may be calculated by solving the Schrödinger equation.

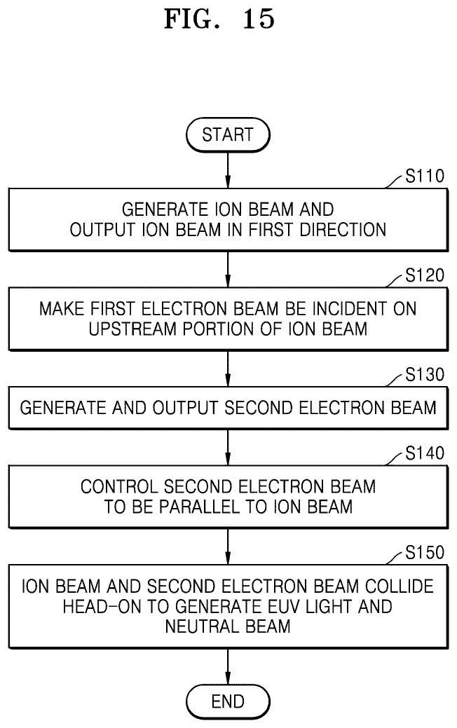

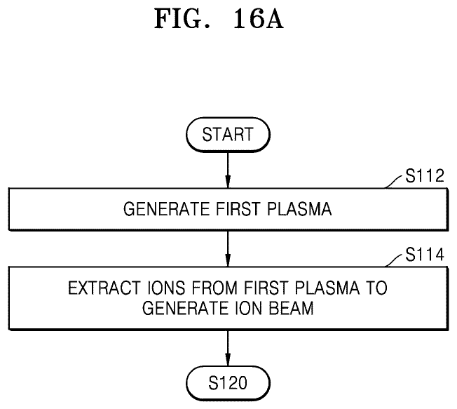

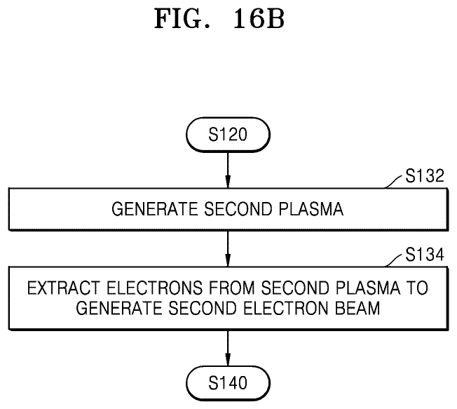

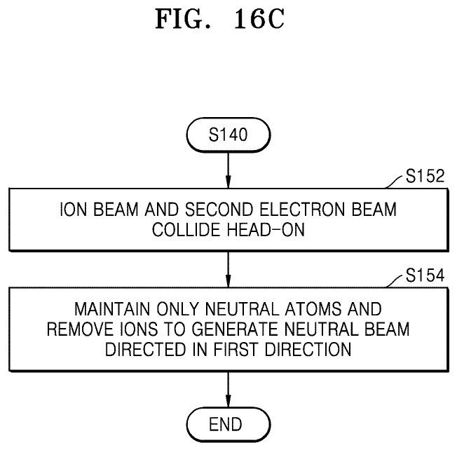

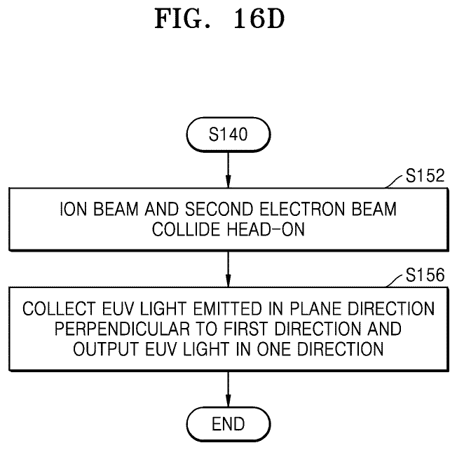

FIG. 15 is a flowchart schematically illustrating processes of a neutral beam and EUV light-generating method according to one or more example embodiments, and FIGS. 16A, 16B, 16C and 16D are flowcharts illustrating the processes of the neutral beam and EUV light-generating method of FIG. 15 in more detail. Description is given with reference to FIG. 1 or 2 together and duplicative description previously given with reference to FIGS. 1, 2, 3, 4A, 4B, 5, 6A, 6B, 7A, 7B, 7C, 8A, 8B, 8C, 9A, 9B, 9C, 10, 11A, 11B, 12A, 12B, 13A, 13B, 14A, 14B may be omitted.

Referring to FIGS. 15 and 16A, in the neutral beam and EUV light-generating method of one or more example embodiments, first, the ion beam I-B is generated by the ion beam source 110 and is output in a first direction, for example, the z direction in operation S110. As noted with reference to FIG. 16A, operation S110 of generating the ion beam I-B and outputting the ion beam I-B in the first direction includes operation S112 of the first plasma generating device 112 generating the first plasma and operation S114 of the first electrostatic lens 114 extracting the ions from the first plasma to generate the ion beam I-B. The generation of the first plasma and the ion beam I-B is similar to the description of the neutral beam and EUV light-generating device 100 of FIG. 1.

Referring to FIG. 15, after generating and outputting the ion beam I-B, the first electron beam source 120 generates the first electron beam 1st E-B and makes the first electron beam 1st E-B be incident on the upstream portion of the ion beam I-B in operation S120. According to one or more example embodiments, the upstream portion of the ion beam I-B may refer to a portion of the ion beam I-B adjacent to the ion beam source 110. The first electron beam 1st E-B may be incident on the ion beam I-B to prevent the ion beam I-B from scattering. In addition, the first electron beam 1st E-B may reduce the influence of the space charge of the ion beam I-B on the speed and orbit of the second electron beam E-B.

Referring to FIGS. 15 and 16B, after the first electron beam 1st E-B is incident on the ion beam I-B, the second electron beam source 130 generates and outputs the second electron beam E-B in operation S130. As noted with reference to FIG. 16B, operation S130 of generating and outputting the second electron beam E-B includes operation S132 of the second plasma generating device 132 generating second plasma, and operation S134 of the second electrostatic lens 134 extracting the electrons from the second plasma to generate the second electron beam E-B. The generation of the second plasma and the second electron beam E-B is similar to the description of the neutral beam and EUV light-generating device 100 of FIG. 1.

Referring to FIG. 15, after generating and outputting the second electron beam E-B, the first electromagnetic control device 140 controls the traveling direction of the second electron beam E-B to be parallel to the ion beam I-B in a direction opposite to the first direction in operation S140. According to one or more example embodiments, the first direction may be the z direction. Accordingly, the ion beam I-B travels downward in the z direction and the first electromagnetic control device 140 may control the second electron beam E-B to travel upward in the z direction. The first electromagnetic control device 140 may control the direction of the second electron beam E-B by changing the orbit of the second electron beam E-B by using the first electromagnetic force EM-F1.

Referring to FIG. 15, after controlling the second electron beam E-B, the ion beam I-B and the second electron beam E-B collide head-on to generate the EUV light EUV and the neutral beam N-B in operation S150.

Referring to FIG. 16C, in operation S150 of generating the EUV light EUV and the neutral beam N-B, a process of generating the neutral beam N-B is described in more detail. Operation S150 of generating the EUV light EUV and the neutral beam N-B may include operation S152 of colliding the ion beam I-B and the second electron beam E-B head-on and operation S154 of maintaining the neutral atoms and removing the ions by using the second electromagnetic control device 150 to generate the neutral beam N-B directed in the first direction. The generation of the neutral beam N-B is similar to the description of the neutral beam and EUV light-generating device 100 of FIG. 1.

Referring to FIG. 16D, in operation S150 of generating the EUV light EUV and the neutral beam N-B, a process of generating the EUV light EUV is described in more detail. Operation S150 of generating the EUV light EUV and the neutral beam N-B may include operation S152 of colliding the ion beam I-B and the second electron beam E-B head-on and operation S156 of collecting the EUV light EUV emitted in a plane direction perpendicular to the first direction by using the EUV collector 160 and outputting the EUV light EUV in one direction. The output of the EUV light EUV by using the EUV collector 160 is similar to the description of the neutral beam and EUV light-generating device 100a of FIG. 2.

Although not described with a flowchart, as in the neutral beam and EUV light-generating device 100b of FIG. 3, operation S150 of generating the EUV light EUV and the neutral beam N-B may include operation S152 of colliding the ion beam I-B and the second electron beam E-B head-on, operation S154 of generating the neutral beam N-B, and operation S156 of collecting the EUV light EUV and outputting the EUV light EUV in one direction.

While one or more example embodiments have been particularly shown and described above, it will be understood that various changes in form and details may be made therein without departing from the spirit and scope of the following claims.

1. A neutral beam and extreme ultraviolet (EUV) light-generating device comprising:
an ion beam source configured to generate an ion beam and to output the ion beam in a first direction;
a first electron beam source configured to generate a first electron beam incident on the ion beam;
a second electron beam source configured to generate and output a second electron beam; and
a first electromagnetic control device configured to control a traveling direction of the second electron beam to cause the second electron beam collide head-on with the ion beam to generate a neutral beam and EUV light.

2. The neutral beam and EUV light-generating device of claim 1, wherein the ion beam source comprises:
a first plasma generating device configured to generate first plasma; and
a first electrostatic lens configured to extract ions from the first plasma and to generate the ion beam.

3. The neutral beam and EUV light-generating device of claim 2, wherein the first plasma generating device is configured to generate capacitively coupled plasma (CCP), inductively coupled plasma (ICP), or plasma comprising a combination of CCP and ICP.

4. The neutral beam and EUV light-generating device of claim 2, wherein the second electron beam source comprises:
a second plasma generating device configured to generate second plasma; and
a second electrostatic lens configured to extract ions from the second plasma and to generate the second electron beam.

5. The neutral beam and EUV light-generating device of claim 4, wherein the second electron beam source is further configured to control energy of the second electron beam by controlling a voltage applied to the second electrostatic lens.

6. The neutral beam and EUV light-generating device of claim 1, further comprising a second electromagnetic control device configured to maintain neutral atoms generated by the second electron beam colliding head-on with the ion beam and to remove ions, wherein the maintained neutral atoms form the neutral beam.

7. The neutral beam and EUV light-generating device of claim 6, wherein the second electron beam source comprises:
a second plasma generating device configured to generate second plasma; and
a second electrostatic lens configured to extract ions from the second plasma and to generate the second electron beam, and
wherein the second electron beam source is further configured to control a voltage applied to the second electrostatic lens so that energy of the second electron beam is lower than ionization energy of the ion beam.

8. The neutral beam and EUV light-generating device of claim 1, further comprising an EUV collector configured to collect EUV light generated from the second electron beam colliding head-on with the ion beam and to output the EUV light in one direction.

9. The neutral beam and EUV light-generating device of claim 8, wherein the second electron beam source comprises:
a second plasma generating device configured to generate second plasma; and
a second electrostatic lens configured to extract ions from the second plasma and to generate the second electron beam, and
wherein the second electron beam source is further configured to control a voltage applied to the second electrostatic lens so that a sum of ionization energy of the ion beam and energy of the second electron beam is substantially equal to energy of EUV light generated.

10. The neutral beam and EUV light-generating device of claim 1, wherein, at the collision of the second electron beam with the ion beam, a wavefront of the ion beam matches a wavefront of the second electron beam so that phase-matched EUV light is generated.

11. The neutral beam and EUV light-generating device of claim 1, wherein, at the collision of the second electron beam with the ion beam, the ion beam and the second electron beam form a dipole in the first direction and EUV light polarized in the first direction is emitted in a plane direction perpendicular to the first direction.

12. The neutral beam and EUV light-generating device of claim 1, wherein the second electron beam source comprises an electron gun or a laser wakefield acceleration (LWFA) device.

13. A neutral beam and extreme ultraviolet (EUV) light-generating device comprising:
an ion beam source configured to extract ions from first plasma to generate an ion beam and to output the ion beam in a first direction;
a first electron beam source configured to generate a first electron beam incident on the ion beam to reduce scattering of the ion beam;
a second electron beam source configured to generate and output a second electron beam, which collides with the ion beam;
a first electromagnetic control device configured to control a traveling direction of the second electron beam to cause the second electron beam to collide head-on with the ion beam; and
a second electromagnetic control device configured to maintain neutral atoms generated by the second electron beam colliding head-on with the ion beam and to remove ions, to generate a neutral beam of the maintained neutral atoms, the neutral beam being directed in the first direction.

14. The neutral beam and EUV light-generating device of claim 13, wherein the ion beam source comprises:
a first plasma generating device configured to generate the first plasma; and
a first electrostatic lens configured to extract ions from the first plasma to generate the ion beam, and
wherein the second electron beam source comprises:
a second plasma generating device configured to generate second plasma; and
a second electrostatic lens configured to extract ions from the second plasma and to generate the second electron beam.

15. The neutral beam and EUV light-generating device of claim 14, wherein the second electron beam source is further configured to control a voltage applied to the second electrostatic lens so that energy of the second electron beam is lower than ionization energy of the ion beam.

16. The neutral beam and EUV light-generating device of claim 13, further comprising an EUV collector configured to collect EUV light generated from the second electron beam colliding head-on with the ion beam and to output the EUV light in one direction.

17. A neutral beam and extreme ultraviolet (EUV) light-generating device comprising:
an ion beam source configured to extract ions from first plasma to generate an ion beam and to output the ion beam in a first direction;
a first electron beam source configured to generate a first electron beam incident on the ion beam to reduce scattering of the ion beam;
a second electron beam source configured to generate and output a second electron beam, which collides with the ion beam;
a first electromagnetic control device configured to control a traveling direction of the second electron beam to cause the second electron beam to collide head-on with the ion beam; and
an EUV collector configured to collect EUV light generated by the second electron beam colliding head-on with the ion beam and to output the EUV light in one direction and in a plane direction perpendicular to the first direction.

18. The neutral beam and EUV light-generating device of claim 17, wherein the ion beam source comprises:
a first plasma generating device configured to generate the first plasma; and
a first electrostatic lens configured to extract ions from the first plasma and to generate the ion beam, and
wherein the second electron beam source comprises:
a second plasma generating device configured to generate second plasma; and
a second electrostatic lens configured to extract ions from the second plasma and to generate the second electron beam.

19. The neutral beam and EUV light-generating device of claim 18, wherein the second electron beam source is further configured to control a voltage applied to the second electrostatic lens so that a sum of ionization energy of the ion beam and energy of the second electron beam is substantially equal to energy of EUV light generated.

20. The neutral beam and EUV light-generating device of claim 17, further comprising a second electromagnetic control device configured to maintain neutral atoms generated by the second electron beam colliding head-on with the ion beam and to remove ions to generate a neutral beam of the maintained neutral atoms, the neutral beam being directed in the first direction.

21.-26. (canceled)
